(19) United States
(12) Patent Application Publication
(10) Pub. No.: US 2025/0287781 A1
(43) Pub. Date: Sep. 11, 2025

(54) DISPLAY DEVICE

(71) Applicant: Samsung Display Co., LTD., Yongin-si (KR)

(72) Inventors: Young Wan SEO, Yongin-si (KR); Jun Hyun PARK, Yongin-si (KR); So Il YOON, Yongin-si (KR)

(73) Assignee: Samsung Display Co., LTD., Yongin-si (KR)

(21) Appl. No.: 19/013,913

(22) Filed: Jan. 8, 2025

(30) Foreign Application Priority Data
Mar. 8, 2024 (KR) 10-2024-0033230

(51) Int. Cl. H10K 59/121

(52) U.S. Cl. CPC H10K 59/1213; H10K 59/1216

(57) ABSTRACT

A display device including a light-emitting element disposed on a substrate, a driving voltage line supplying a driving voltage, a first transistor that controls a driving current supplied to the light-emitting element, a second transistor that provides a data voltage to a gate electrode of the first transistor, a third transistor that provides a driving voltage to a drain electrode of the first transistor, a first capacitor including a first electrode electrically connected to the gate electrode of the first transistor and a second electrode electrically connected to a first electrode of the light-emitting element, and a second capacitor including a first electrode electrically connected to the driving voltage line and a second electrode electrically connected to the first electrode of the light-emitting element. The first electrode and the second electrode of the second capacitor are above the first electrode and the second electrode of the first capacitor.

### CROSS-REFERENCE TO RELATED APPLICATION(S)

This application claims priority to and benefits of Korean Patent Application No. 10-2024-0033230 under 35 U.S.C. § 119 filed on Mar. 8, 2024, in the Korean Intellectual Property Office, the entire contents of which are incorporated herein by reference.

### BACKGROUND

### 1. Technical Field

The disclosure relates to a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. Display devices may be flat panel display devices such as a liquid-crystal display device, a field emission display device, and an organic light-emitting display device. Among such flat panel display devices, a light-emitting display device may include a light-emitting element that can emit light on its own, so that each of the pixels of the display panel can emit light by themselves. Accordingly, a light-emitting display device can display images without a backlight unit that supplies light to the display panel.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device that allows high-resolution pixels to be readily designed by reducing the area of a pixel circuit.

It should be noted that objects of the disclosure are not limited to the above-mentioned objects; and other objects of the disclosure will be apparent to those skilled in the art from the following descriptions.

According to an embodiment, a display device may include a light-emitting element disposed on a substrate; a driving voltage line supplying a driving voltage; a first transistor that controls a driving current supplied to the light-emitting element; a second transistor that provides a data voltage to a gate electrode of the first transistor; a third transistor that provides a driving voltage to a drain electrode of the first transistor; a first capacitor comprising a first electrode electrically connected to the gate electrode of the first transistor and a second electrode electrically connected to a first electrode of the light-emitting element; and a second capacitor comprising a first electrode electrically connected to the driving voltage line and a second electrode electrically connected to the first electrode of the light-emitting element. The first electrode and the second electrode of the second capacitor are disposed above the first electrode and the second electrode of the first capacitor.

The display device may further comprise a metal layer disposed on the substrate, an active layer disposed on the metal layer, the active layer comprising a semiconductor region of each of the first transistor, the second transistor, and the third transistor, a first gate layer disposed on the active layer, the first gate layer comprising a gate electrode of each of the first transistor, the second transistor, and the third transistor, a second gate layer disposed on the first gate layer, a first source metal layer disposed on the second gate layer, and a second source metal layer disposed on the first source metal layer. The first gate layer and the second gate layer may include a first material, and the first source metal layer and the second source metal layer may include a second material different from the first material.

The active layer may include an oxide-based semiconductor region.

The first electrode of the first capacitor may be formed as the first gate layer, and the second electrode of the first capacitor may be formed as the second gate layer. The first electrode of the second capacitor may be formed as the first source metal layer, and the second electrode of the second capacitor may be formed as the second source metal layer.

The driving voltage line may comprise a first portion formed as the first source metal layer and extended in a first direction, and a second portion formed as the second source metal layer and extended in the first direction.

The first portion of the driving voltage line may comprise the first electrode of the second capacitor. The second portion of the driving voltage line may supply the driving voltage to a drain electrode of the third transistor.

The display device may further comprise an anode connection electrode formed as the second source metal layer, comprising the second electrode of the second capacitor, and electrically connecting a source electrode of the first transistor to the first electrode of the light-emitting element.

The display area may further comprise a display area comprising the light-emitting element, the first transistor, the second transistor and the third transistor, and the first capacitor and the second capacitor, and a non-display area surrounding the display area. The first portion and the second portion of the driving voltage line may be spaced apart from each other in the display area and connected to each other in the non-display area.

The first portion and the second portion of the driving voltage line may overlap each other and may be connected to each other in a display area.

The display device may further comprise a third source metal layer disposed on the second source metal layer. The first electrode of the second capacitor may be formed as the second source metal layer, and the second electrode of the second capacitor may be formed as the third source metal layer.

The display device may further comprise a third source metal layer disposed on the second source metal layer, and a fourth source metal layer disposed on the third source metal layer. The first electrode of the second capacitor may be formed as the third source metal layer, and the second electrode of the second capacitor may be formed as the fourth source metal layer.

The display device may further comprise a metal layer disposed on the substrate, an active layer disposed on the metal layer, the active layer comprising a semiconductor region of each of the first transistor, the second transistor, and the third transistor, a first gate layer disposed on the active layer, the first gate layer comprising a gate electrode of each of the first transistor, the second transistor, and the third transistor, a second gate layer disposed on the first gate layer, a third gate layer disposed on the second gate layer, and a source metal layer disposed on the third gate layer. The first gate layer, the second gate layer, and the third gate layer may include a first material, and the source metal layer may include a second material different from the first material.

The first electrode of the first capacitor may be formed as the first gate layer, and the second electrode of the first capacitor may be formed as the second gate layer. The first electrode of the second capacitor may be formed as the third gate layer, and the second electrode of the second capacitor may be formed as the source metal layer.

According to an embodiment, a display device may include a light-emitting element disposed on a substrate; a driving voltage line comprising a first portion extended in a first direction and a second portion disposed on the first portion and extended in the first direction; a first transistor that controls a driving current supplied to the light-emitting element; a capacitor electrode disposed on a gate electrode of the first transistor and electrically connected to a first electrode of the light-emitting element; a second transistor that supplies a data voltage to the gate electrode of the first transistor; a third transistor that receives a driving voltage from the second portion of the driving voltage line to supply the driving voltage to a drain electrode of the first transistor; an anode connection electrode formed as a same layer as the second portion of the driving voltage line and electrically connecting the first transistor to the light-emitting element; a first capacitor comprising a first electrode comprising the gate electrode of the first transistor, and a second electrode corresponding to a part of the capacitor electrode, and a second capacitor comprising a first electrode corresponding to a part of the first portion of the driving voltage line, and a second electrode corresponding to a part of the anode connection electrode.

The display device may further comprise a metal layer disposed on the substrate, an active layer disposed on the metal layer, the active layer comprising a semiconductor region of each of the first transistor, the second transistor and the third transistor, a first gate layer disposed on the active layer, the first gate layer comprising a gate electrode of each of the first transistor, the second transistor and the third transistor, a second gate layer disposed on the first gate layer, a first source metal layer disposed on the second gate layer, and a second source metal layer disposed on the first source metal layer. The first and second gate layers may include a first material, and the first source metal layer and the second source metal layer may include a second material different from the first material.

The gate electrode of the first transistor may be formed as the first gate layer, and the capacitor electrode may be formed as the second gate layer. The first portion of the driving voltage line may be formed as the first source metal layer, and the anode connection electrode may be formed as the second source metal layer.

The display device may further comprise a third source metal layer disposed on the second source metal layer. The first portion of the driving voltage line may be formed as the second source metal layer, and the anode connection electrode may be formed as the third source metal layer.

The display device may further comprise a third source metal layer disposed on the second source metal layer; and a fourth source metal layer disposed on the third source metal layer. The first portion of the driving voltage line may be formed as the third source metal layer, and the anode connection electrode may be formed as the fourth source metal layer.

The display device may further comprise a display area comprising the light-emitting element, the first transistor, the second transistor and the third transistor, and the first capacitor and the second capacitor, and a non-display area surrounding the display area. The first portion and the second portion of the driving voltage line may be spaced apart from each other in the display area and connected to each other in the non-display area.

The first portion and the second portion of the driving voltage line may overlap each other and may be connected to each other in a display area.

According to an embodiment, an electronic device, includes a display module configured to provide an image, and a processor configured to transmit an image data signal to the display module. The display module includes a light-emitting element disposed on a substrate, a driving voltage line supplying a driving voltage, a first transistor that controls a driving current supplied to the light-emitting element, a second transistor that provides a data voltage to a gate electrode of the first transistor, a third transistor that provides a driving voltage to a drain electrode of the first transistor, a first capacitor comprising a first electrode electrically connected to the gate electrode of the first transistor and a second electrode electrically connected to a first electrode of the light-emitting element, and a second capacitor comprising a first electrode electrically connected to the driving voltage line and a second electrode electrically connected to the first electrode of the light-emitting element. The first electrode and the second electrode of the second capacitor are disposed above the first electrode and the second electrode of the first capacitor.

According to embodiments, a display device may include a first capacitor formed between first and second gate layers and a second capacitor formed between first and second source metal layers, so that the area of a pixel circuit can be reduced by reducing the line width and pixel design space, and a voltage drop can be reduced. Accordingly, the display device can be readily employed for small-sized devices.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view showing a display device according to an embodiment.

FIG. 2 is a schematic cross-sectional view showing a display device according to an embodiment.

FIG. 3 is a schematic plan view showing a display unit of a display device according to an embodiment.

FIG. 4 is a block diagram illustrating the display panel and the display driver according to an embodiment.

FIG. 5 is a schematic diagram of an equivalent of a pixel of a display device according to an embodiment.

FIG. 6 is a schematic view showing a layout of a pixel of a display device according to an embodiment.

FIG. 7 is a schematic view showing layers of the view of FIG. 6.

FIG. 8 is a schematic view showing other layers of the view of FIG. 6.

FIG. 9 is a schematic cross-sectional view, taken along line I-I′ of FIGS. 6 to 8.

FIG. 10 is a schematic view showing a layout of layers of a pixel in a display device according to an embodiment.

FIG. 11 is a schematic cross-sectional view showing a pixel in a display device according to an embodiment.

FIG. 12 is a schematic cross-sectional view showing a pixel in a display device according to an embodiment.

FIG. 13 is a schematic cross-sectional view showing a pixel in a display device according to an embodiment.

FIG. 14 is a block diagram of an electronic device according to an embodiment of the disclosure.

FIG. 15 is a schematic diagram of an electronic device according to various embodiments of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless noted.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein should be interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terminology used herein is for the purpose of describing embodiments and is not intended to be limiting. As used herein, the singular forms, “a,” “an,” and “the” are intended to include the plural forms as well, unless the context clearly indicates otherwise.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (for example, microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (for example, one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described in detail with reference to the accompanying drawings.

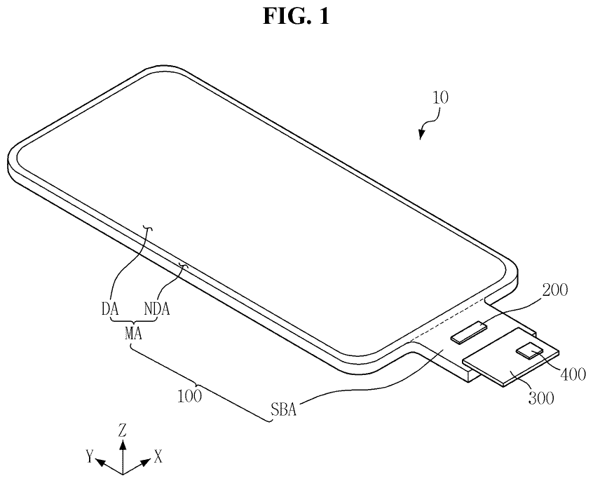

FIG. 1 is a schematic perspective view showing a display device according to an embodiment.

Referring to FIG. 1, a display device 10 may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IOT). For another example, the display device 10 may be applied to wearable devices such as a smart watch, a watch phone, a glasses-type display, and a head-mounted display (HMD) device.

The display device 10 may have a shape similarly to a quadrangular shape when viewed from the top. For example, the display device 10 may have a shape similar to a rectangle having shorter sides in the x-axis direction and longer sides in the y-axis direction when viewed from the top. The corners where the shorter sides in the x-axis direction and the longer sides in the y-axis direction meet may be rounded to have a selectable curvature or may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include a display area DA having pixels for displaying images, and a non-display area NDA located or disposed around the display area DA. The display area DA may output lights from a plurality of emission areas or a plurality of open areas. For example, the display panel 100 may include a pixel circuit including switching elements, a pixel-defining layer that defines the emission areas or the open areas, and self-light-emitting elements.

For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be located or disposed on an outer side of the display area DA. The non-display area NDA may be defined as the edge of the main area MA of the display panel 100. The non-display area NDA may include a scan driver that provides scan signals to scan lines, and fan-out lines that connect the display driver 200 with the display area DA.

The subsidiary area SBA may be extended from one side or a side of the main area MA. The subsidiary area SBA may include a flexible material that can be bent, folded, or rolled. For example, in case that the subsidiary area SBA is bent, the subsidiary area SBA may overlap the main area MA in the thickness direction (z-axis direction). The subsidiary area SBA may include pads connected to the display driver 200 and the circuit board 300. Optionally, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a power line, and may supply a scan control signal to the scan driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap the main area MA in the thickness direction (z-axis direction) as the subsidiary area SBA is bent. For another example, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and may sense a change in the capacitance between the plurality of touch electrodes. For example, the touch driving signals may be pulse signals having a selectable frequency. The touch driver 400 may determine whether there is an input and may find the coordinates of the input based on the amount of the change in the capacitance between the touch electrodes. The touch driver 400 may be implemented as an integrated circuit (IC).

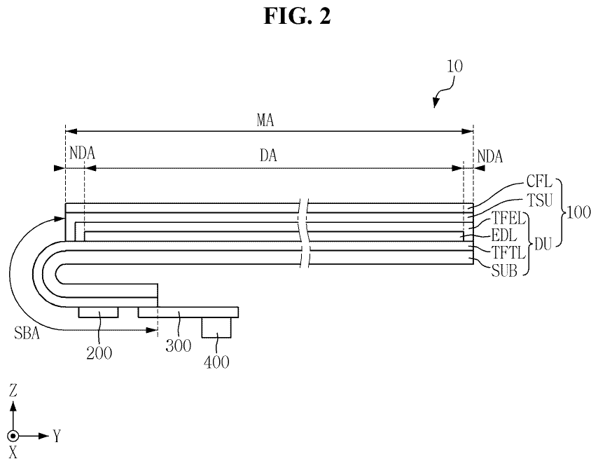

FIG. 2 is a schematic cross-sectional view showing a display device according to an embodiment.

Referring to FIG. 2, the display panel 100 may include a display unit DU, a touch sensing unit TSU, and a color filter layer CFL. The display unit DU may include a substrate SUB, a transistor layer TFTL, an emission material layer EDL and an encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide PI. For another example, the substrate SUB may include a glass material or a metal material.

The transistor layer TFTL may be disposed on the substrate SUB. The transistor layer TFTL may include a plurality of transistors forming pixel circuits of pixels. The transistor layer TFTL may further include scan lines, data lines, voltage lines, scan control lines, fan-out lines for connecting the display driver 200 with the data lines, lead lines for connecting the display driver 200 with the pads, etc. Each of the transistors may include a semiconductor region, a source electrode, a drain electrode, and a gate electrode. For example, in case that the scan driver is formed in the non-display area NDA of the display panel 100, the scan driver may include transistors.

The transistor layer TFTL may be disposed in the display area DA, the non-display area NDA and the subsidiary area SBA. Transistors, scan lines, data lines and power lines in the transistor layer TFTL for the pixels may be disposed in the display area DA. The scan control lines and the fan-out lines in the transistor layer TFTL may be disposed in the non-display area NDA. The lead lines of the transistor layer TFTL may be disposed in the subsidiary area SBA.

The emission material layer EDL may be disposed on the transistor layer TFTL. The emission material layer EDL may include a plurality of light-emitting elements in each of which a first electrode, an emissive layer and a second electrode are stacked each other sequentially to emit light, and a pixel-defining layer for defining the pixels. The plurality of light-emitting elements in the emission material layer EDL may be disposed in the display area DA.

For example, the emissive layer may be an organic light-emitting layer containing an organic material. The emissive layer may include a hole transporting layer, an organic light-emitting layer and an electron transporting layer. In case that the first electrode receives a voltage and the second electrode receives a cathode voltage through the transistors in the transistor layer TFTL, holes may move to the organic light-emitting layer through the hole transporting layer and electrons may move to the organic light-emitting layer through the electron transporting layer, such that the holes and the electrons combine in the organic light-emitting layer to emit light. For example, the first electrode may be an anode electrode or a pixel electrode, while the second electrode may be a cathode electrode or a common electrode. It is, however, to be understood that the disclosure is not limited thereto.

As another example, the light-emitting elements may include quantum-dot light-emitting diodes each including a quantum-dot emissive layer, inorganic light-emitting diodes each including an inorganic semiconductor, or micro light-emitting diodes.

The encapsulation layer TFEL may cover the upper and side surfaces of the emission material layer EDL, and can protect the emission material layer EDL. The encapsulation layer TFEL may include at least one inorganic layer and at least one organic layer for encapsulating the emission material layer EDL.

The touch sensing unit TSU may be disposed on the encapsulation layer TFEL. The touch sensing unit TSU may include a plurality of touch electrodes for sensing a user's touch by capacitive sensing, and touch lines connecting the plurality of touch electrodes with the touch driver 400. For example, the touch sensing unit TSU may sense a user's touch by mutual capacitance sensing or self-capacitance sensing. The plurality of touch electrodes of the touch sensing unit TSU may be disposed in a touch sensor area overlapping the display area DA. The touch lines of the touch sensing unit TSU may be disposed in a touch peripheral area overlapping the non-display area NDA.

For another example, the touch sensing unit TSU may be disposed on a separate substrate disposed on the display unit DU. In such case, the substrate supporting the touch sensing unit TSU may be a base member encapsulating the display unit DU.

The color filter layer CFL may be disposed on the touch sensing unit TSU. The color filter layer CFL may include a plurality of color filters associated with the plurality of emission areas, respectively. Each of the color filters may selectively transmit light of a selectable wavelength and block or absorb lights of other wavelengths. The color filter layer CFL may absorb some lights introduced from the outside of the display device 10 to reduce the reflection of external light. Accordingly, the color filter layer CFL can prevent distortion of colors due to the reflection of external light.

Since the color filter layer CFL is disposed directly on the touch sensing unit TSU, the display device 10 may require no separate substrate for the color filter layer CFL. Therefore, the thickness of the display device 10 can be relatively reduced.

The subsidiary area SBA of the display panel 100 may be extended from one side or a side of the main area MA. The subsidiary area SBA may include a flexible material that can be bent, folded, or rolled. For example, in case that the subsidiary area SBA is bent, the subsidiary area SBA may overlap the main area MA in the thickness direction (z-axis direction). The subsidiary area SBA may include pads electrically connected to the display driver 200 and the circuit board 300.

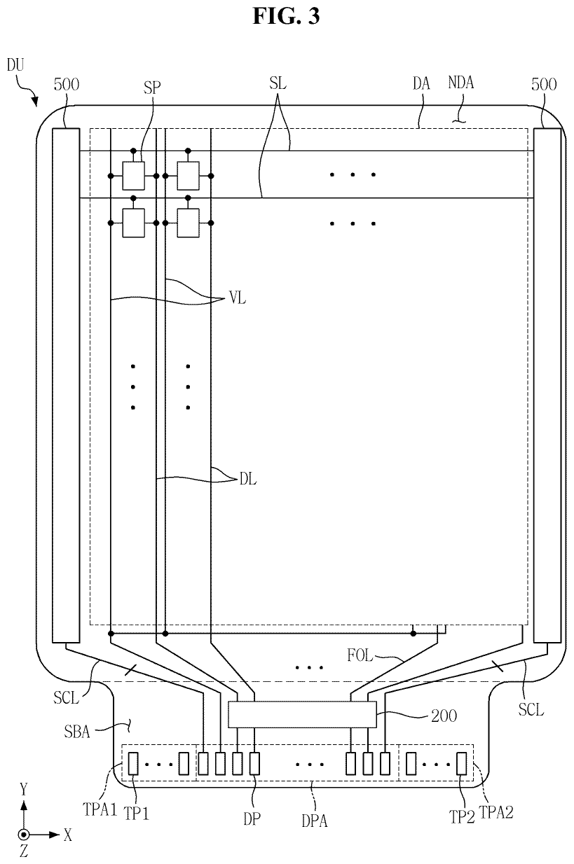

FIG. 3 is a schematic plan view showing a display unit of a display device according to an embodiment.

Referring to FIG. 3, the display unit DU may include a display area DA and a non-display area NDA.

The display area DA displays images therein and may be defined as a central area of the display panel 100. The display area DA may include a plurality of pixels SP, a plurality of scan lines SL, a plurality of data lines DL and a plurality of voltage lines VL. Each of the plurality of pixels SP may be defined as the minimum unit that outputs light.

The plurality of scan lines SL may provide the scan signals received from the scan driver 500 to the plurality of pixels SP. The plurality of scan lines SL may be extended in the x-axis direction and may be spaced apart from one another in the y-axis direction intersecting the x-axis direction.

The plurality of data lines DL may supply the data voltages received from the display driver 200 to the plurality of pixels SP. The plurality of data lines DL may be extended in the y-axis direction and may be spaced apart from one another in the x-axis direction.

The plurality of voltage lines VL may supply the supply voltage received from display pads DP to the plurality of pixels SP. The supply voltage may be at least one of a driving voltage, a high-level voltage, an initialization voltage, a reference voltage, a bias voltage, and a low-level voltage. The plurality of voltage lines VL may be extended in the y-axis direction and may be spaced apart from one another in the x-axis direction.

The non-display area NDA may surround or may be adjacent to the display area DA. The non-display area NDA may include the scan driver 500, fan-out lines FOL, and scan control lines SCL. The scan driver 500 may generate a plurality of scan signals based on a scan control signal, and may sequentially supply the scan signals to the scan lines SL in a selectable order.

The fan-out lines FOL may be extended from the display driver 200 to the display area DA. The fan-out lines FOL may supply the data voltage received from the display driver 200 to the plurality of data lines DL.

A scan control line SCL may be extended from the display pads DP to the scan driver 500. The scan control line SCL may provide the scan control signal received from the display pads DP to the scan driver 500.

The subsidiary area SBA may include the display driver 200, a display pad area DPA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels SP, so that the luminance of the plurality of pixels SP may be determined.

The display pad area DPA, the first touch pad area TPA1 and the second touch pad area TPA2 may be disposed on the edge of the subsidiary area SBA. The display pad area DPA, the first touch pad area TPA and the second touch pad area TPA2 may be electrically connected to the circuit board 300 using a low-resistance, high-reliable material such as an anisotropic conductive film and a self assembly anisotropic conductive paste (SAP).

The display pad area DPA may include a plurality of display pads DP. The plurality of display pads DP may be electrically connected to a graphic system through the circuit board 300. The plurality of display pads DP may be connected to the circuit board 300 to receive digital video data and may supply the digital video data to the display driver 200. The display pads DP may supply a scan control signal to the scan driver 500 through the scan control line SCL.

The first touch pad area TPA1 may be disposed on one side or a side of the display pad area DPA and may include a plurality of first touch pads TP1. The plurality of first touch pads TP1 may be electrically connected to the touch driver 400 disposed on the circuit board 300. The plurality of first touch pads TP1 may supply touch driving signals to a plurality of driving electrodes through a plurality of driving lines.

The second touch pad area TPA2 may be disposed on the opposite side of the display pad area DPA and may include a plurality of second touch pads TP2. The plurality of second touch pads TP2 may be electrically connected to the touch driver 400 disposed on the circuit board 300. The touch driver 400 may receive a touch sensing signal through a plurality of sensing lines connected to the plurality of second touch pads TP2, and may sense a change in the capacitance between the driving electrodes and sensing electrodes.

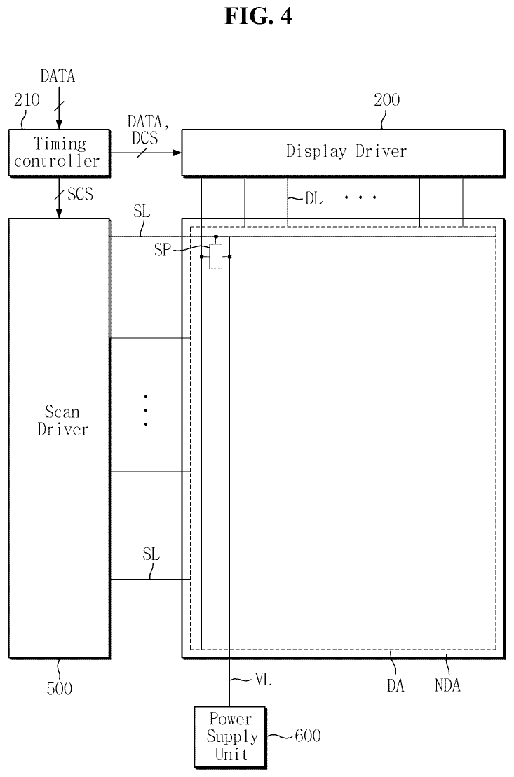

FIG. 4 is a block diagram illustrating the display panel and the display driver according to an embodiment.

Referring to FIG. 4, a display panel 100 may include a display area DA and a non-display area NDA.

The display area DA may include a plurality of pixels SP, a plurality of voltage lines VL connected to the pixels SP, a plurality of scan lines SL, and a plurality of data lines DL.

Each of the pixels SP may be connected to a scan line SL, a data line DL, and a voltage line VL. Each of the pixels SP may include a transistor, a light-emitting clement, and a capacitor.

The scan lines SL may be extended in the x-axis direction and may be spaced apart from one another in the y-axis direction intersecting the x-axis direction. The scan lines SL may sequentially supply scan signals to the plurality of pixels SP.

The data lines DL may be extended in the y-axis direction and may be spaced apart from one another in the x-axis direction. The data lines DL may supply data voltages to the pixels SP. The data voltage may determine the luminance of each of the plurality of pixels SP.

The voltage lines VL may be extended in the y-axis direction and may be spaced apart from one another in the x-axis direction. The voltage lines VL may supply voltage to the plurality of pixels SP. The supply voltage may be at least one of a driving voltage, a high-level voltage, an initialization voltage, a reference voltage, a bias voltage, and a low-level voltage.

The timing controller 210 may receive digital video data DATA and timing signals from the circuit board 300. The timing controller 210 may generate a data control signal DCS based on the timing signals. The timing controller 210 may supply the digital video data DATA and the data control signal DCS to the display driver 200 to control the operation timing of the display driver 200. The display driver 200 may convert the digital video data DATA into analog data voltages and may supply them to the data lines DL. The timing controller 210 may generate a scan control signal SCS based on the timing signals. The timing controller 210 may control the operation timing of the scan driver 500 by supplying the scan control signal SCS to the scan driver 500. The scan driver 500 may be disposed on at least one of the left side and the right side of the non-display area NDA.

The scan driver 500 may include a plurality of transistors and may generate scan signals based on the scan control signal SCS. The scan signals of the scan driver 500 may be used to select pixels SP to which data voltages are applied, and the selected pixels SP may receive the data voltages through the data lines DL. For example, the transistors of the scan driver 500 may be formed in the same layer as the transistors of the pixel SP. The scan driver 500 may supply scan signals to the scan lines SL.

A power supply unit 600 may apply supply voltages to the display driver 200 and the display panel 100. The power supply unit 600 may generate a driving voltage to supply it to a driving voltage line, may generate an initialization voltage to supply it to an initialization voltage line, may generate a bias voltage to supply it to a bias voltage line, and may generate a low-level voltage to supply it to a low-level voltage line.

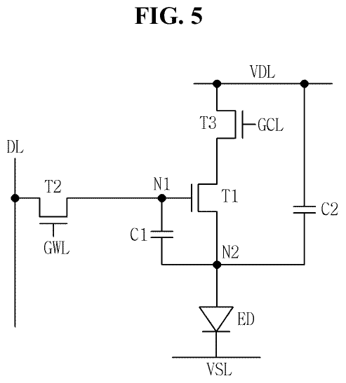

FIG. 5 is a schematic diagram of an equivalent of a pixel of a display device according to an embodiment.

Referring to FIG. 5, the pixel SP may be connected to a first scan line GWL, a second scan line GCL, a data line DL, a driving voltage line VDL, and a low-level voltage line VSL.

The pixel SP may include a light-emitting element ED and a pixel circuit that drives the light-emitting element ED. The pixel circuit may include first to third transistors T1, T2 and T3, and first and second capacitors C1 and C2.

The first transistor T1 may control a driving current supplied to the light-emitting element ED. The first transistor T1 may include a gate electrode, a drain electrode and a source electrode. The gate electrode of the first transistor TI may be connected to a first node N1, the drain electrode thereof may be connected to a third transistor T3, and the source electrode thereof may be connected to a second node N2. The first transistor T1 may control the drain-source current Ids (hereinafter, referred to as “driving current”) according to the data voltage applied to the gate electrode. The driving current Ids flowing through the channel of the first transistor T1 may be proportional to the square of the difference between the threshold voltage Vth and the voltage Vgs between the gate electrode and the source electrode of the first transistor T1(Ids=k′×(Vgs−Vth)²), where k denotes a proportional coefficient determined by the structure and physical properties of the first transistor TI, Vgs denotes the drain-source voltage of the first transistor T1, and Vth denotes the threshold voltage of the first transistor T1.

The light-emitting element ED may receive the driving current Ids to emit light. The amount or the luminance of the light emitted from the light-emitting element ED may be proportional to the magnitude of the driving current Ids. The light-emitting element ED may include a first electrode, a second electrode, and an emissive layer disposed between the first electrode and the second electrode. The first electrode of the light-emitting element ED may be connected to a second node N2. The first electrode of the light-emitting element ED may be electrically connected to the source electrode of the first transistor T1, a second electrode of the first capacitor C1, and a second electrode of the second capacitor C2 through the second node N2. The second electrode of the light-emitting element ED may be connected to the low-level voltage line VSL to receive a low-level voltage from it. For example, the first electrode of the light-emitting element ED may be an anode electrode or a pixel electrode, while the second electrode thereof may be a cathode electrode or a common electrode. It is, however, to be understood that the disclosure is not limited thereto.

The second transistor T2 may be turned on by a first scan signal of the first scan line GWL to electrically connect the data line DL with the first node N1, which is the gate electrode of the first transistor T1. The second transistor T2 may be turned on in response to the first scan signal to apply data voltage to the first node N1. The gate electrode of the second transistor T2 may be connected to the first scan line GWL, the drain electrode thereof may be connected to the data line DL, and the source electrode thereof may be connected to the first node N1.

The third transistor T3 may be turned on by a second scan signal of the second scan line GCL to electrically connect the drain electrode of the first transistor T1 with the driving voltage line VDL. The gate electrode of the third transistor T3 may be connected to the second scan line GCL, the drain electrode thereof may be connected to the driving voltage line VDL, and the source electrode thereof may be connected to the drain electrode of the first transistor T1.

In case that the third transistor T3 and the first transistor T1 both are turned on, the driving current Ids may be supplied to the light-emitting element ED.

The first to third transistors T1, T2, and T3 may include an oxide-based semiconductor region. For example, each of the first to third transistors T1, T2 and T3 may have a coplanar structure in which a gate electrode is disposed above an oxide-based semiconductor region. A transistor having such a coplanar structure has excellent leakage current characteristics and allows for low-frequency driving, thereby reducing power consumption. Accordingly, the display device 10 may include the first to third transistors T1, T2 and T3 having good leakage current characteristics, so that it is possible to prevent leakage current from flowing inside the pixels, and to maintain the voltage inside the pixels stably.

The first to third transistors T1, T2 and T3 may be n-type transistors. Each of the first to third transistors T1, T2 and T3 may include a drain electrode and a source electrode doped into n-type. For example, each of the first to third transistors T1, T2 and T3 may output a current flowing into the drain electrode to the source electrode in response to a gate-high voltage applied to the gate electrode.

The first capacitor C1 may be connected between the first node N1, which is the gate electrode of the first transistor ST1, and the second node N2, which is the first electrode of the light-emitting element ED. For example, the first electrode of the first capacitor C1 may be connected to the first node N1, the second electrode of the first capacitor C1 may be connected to the second node N2, so that a potential difference between the gate electrode of the first transistor T1 and the first electrode of the light-emitting element ED can be maintained.

The second capacitor C2 may be connected between the second node N2 which is the first electrode of the light-emitting element ED and the driving voltage line VDL. For example, the first electrode of the second capacitor C2 may be connected to the first node N1, the second electrode of the second capacitor C2 may be connected to the driving voltage line VDL, such that the potential difference between the first electrode of the light-emitting element ED and the driving voltage line VDL can be maintained.

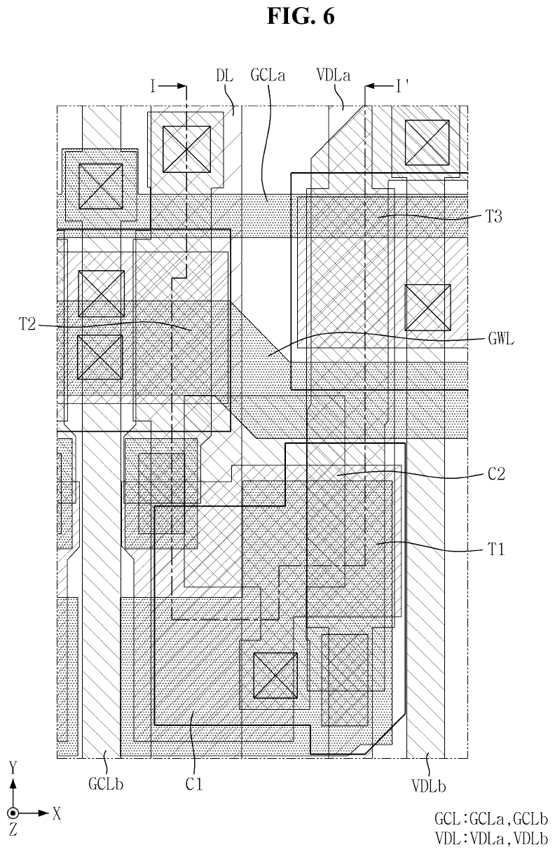

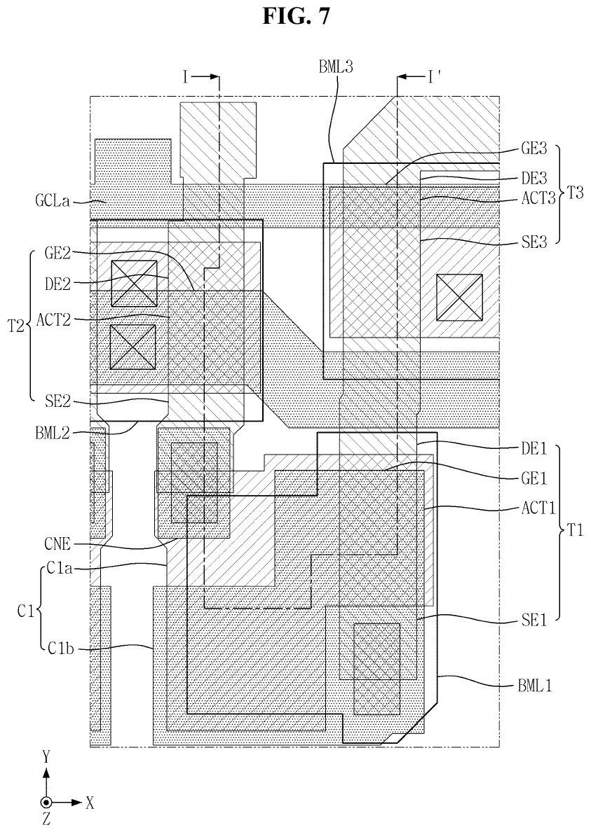

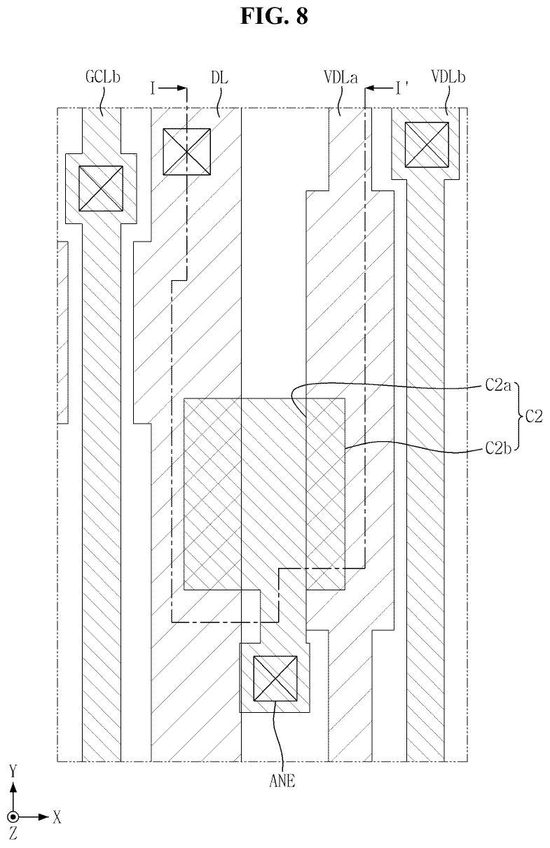

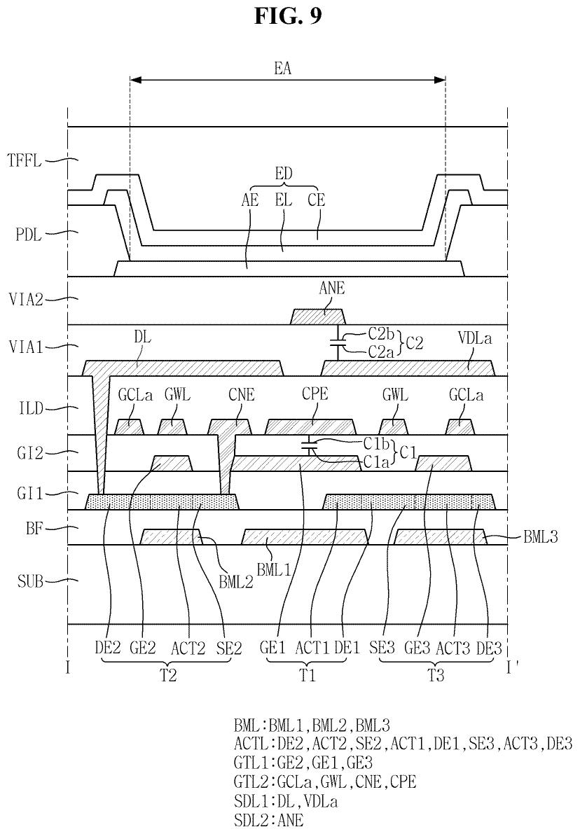

FIG. 6 is a view showing a layout of a pixel of a display device according to an embodiment. FIG. 7 is a view showing layers of the view of FIG. 6, showing a stacked structure of a metal layer BML, an active layer ACTL, a first gate layer GTL1, and a second gate layer GTL2. FIG. 8 is a view showing other layers of the view of FIG. 6, showing a stacked structure of a first source metal layer SDL1 and a second source metal layer SDL2. FIG. 9 is a schematic cross-sectional view, taken along line I-I′ of FIGS. 6 to 8.

Referring to FIGS. 6 to 9, the pixel SP may be connected to a first scan line GWL, a second scan line GCL, a data line DL, a driving voltage line VDL, and a low-level voltage line VSL.

The first transistor T1 may include a semiconductor region ACT1, a drain electrode DE1, a source electrode SE1 and a gate electrode GE1. The semiconductor region ACT1, the drain electrode DE1 and the source electrode SE1 of the first transistor T1 may be disposed in (or formed as) the active layer ACTL, and the gate electrode GE1 of the first transistor T1 may be disposed in (or formed as) the first gate layer GTL1. The gate electrode GE1 of the first transistor T1 may be a part of a first electrode Cla of the first capacitor C1 and may overlap the semiconductor region ACT1 of the first transistor T1. For example, the semiconductor region ACT1 of the first transistor T1 may include an oxide, and the drain electrode DEI and the source electrode SE1 of the first transistor T1 may be doped into n-type.

The gate electrode GE1 of the first transistor T1 may be electrically connected to the source electrode SE2 of the second transistor T2 through a connection electrode CNE of the second gate layer GTL2. The drain electrode DEI of the first transistor ST1 may be integral with a source electrode SE3 of the third transistor T3. The source electrode SE1 of the first transistor T1 may be electrically connected to the first electrode AE of the light-emitting element ED through the capacitor electrode CPE of the second gate layer GTL2 and the anode connection electrode ANE of the second source metal layer SDL2.

The second transistor T2 may include a semiconductor region ACT2, a drain electrode DE2, a source electrode SE2 and a gate electrode GE2. The semiconductor region ACT2, the drain electrode DE2 and the source electrode SE2 of the second transistor T2 may be disposed in (or formed as) the active layer ACTL, and the gate electrode GE2 of the second transistor T2 may be disposed in (or formed as) the first gate layer GTL1. The gate electrode GE2 of the second transistor T2 may overlap the semiconductor region ACT2 of the second transistor T2. For example, the semiconductor region ACT2 of the second transistor T2 may include an oxide, and the drain electrode DE2 and the source electrode SE2 of the second transistor T2 may be doped into n-type.

The gate electrode GE2 of the second transistor T2 may be connected to the first scan line GWL of the second gate layer GTL2 to receive the first scan signal. The first scan line GWL may be extended in the x-axis direction between the first and third transistors T1 and T3. The drain electrode DE2 of the second transistor T2 may be connected to the data line DL of the first source metal layer SDL1 to receive a data voltage. The source electrode SE2 of the second transistor ST2 may be electrically connected to the gate electrode GE1 of the first transistor T1 through the connection electrode CNE.

The third transistor ST3 may include a semiconductor region ACT3, a drain electrode DE3, a source electrode SE3 and a gate electrode GE3. The semiconductor region ACT3, the drain electrode DE3 and the source electrode SE3 of the third transistor T3 may be disposed in (or formed as) the active layer ACTL, and the gate electrode GE3 of the third transistor T3 may be disposed in (or formed as) the first gate layer GTL1. The gate electrode GE3 of the third transistor T3 may overlap the semiconductor region ACT3 of the third transistor T3. For example, the semiconductor region ACT3 of the third transistor T3 may include an oxide, and the drain electrode DE3 and the source electrode SE3 of the third transistor T3 may be doped into n-type.

The gate electrode GE3 of the third transistor T3 may be connected to a first portion GCLa of the second scan line GCL to receive the second scan signal. The first portion GCLa of the second scan line GCL may be disposed in (or formed as) the second gate layer GTL2 and may be extended in the x-axis direction, and a second portion GCLb of the second scan line GCL may be disposed in (or formed as) the second source metal layer SDL2 and may be extended in the y-axis direction. The drain electrode DE3 of the third transistor T3 may be connected to a second portion VDLb of the driving voltage line VDL to receive a driving voltage or a high-level voltage. The second portion VDLb of the driving voltage line VDL may be disposed in (or formed as) the second source metal layer SDL2 and may be extended in the y-axis direction. The source electrode SE3 of the third transistor T3 may be integral with the drain electrode DE1 of the first transistor T1.

The first capacitor C1 may include the first electrode Cla and a second electrode Clb. The first and second electrodes Cla and Clb of the first capacitor C1 may overlap each other. The first electrode Cla of the first capacitor C1 may be disposed in (or formed as) the first gate layer GTL1, and the second electrode Clb may be disposed in (or formed as) the second gate layer GTL2. The first electrode Cla of the first capacitor C1 may include the gate electrode GE1 of the first transistor T1, and the second electrode Clb may be a part of the capacitor electrode CPE. The capacitor electrode CPE may be connected to the source electrode SE1 of the first transistor T1 and the anode connection electrode ANE. Accordingly, the first capacitor C1 may be formed between the first and second gate layers GTL1 and GTL2.

The second capacitor C2 may include a first electrode C2a and a second electrode C2b. The first and second electrodes C2a and C2b of the second capacitor C2 may overlap each other. The first electrode C2a of the second capacitor C2 may be disposed in (or formed as) the first source metal layer SDL1, and the second electrode C2b may be disposed in (or formed as) the second source metal layer SDL2. The first electrode C2a of the second capacitor C2 may be a part of the first portion VDLa of the driving voltage line VDL of the first source metal layer SDL1. The first portion VDLa and the second portion VDLb of the driving voltage line VDL may be spaced apart from each other in the display area DA and may be extended in parallel in the y-axis direction when viewed from the top. The first portion VDLa and the second portion VDLb of the driving voltage line VDL may be connected to each other in the non-display area NDA, but the connection location is not limited thereto. The second electrode C2b of the second capacitor C2 may be a part of the anode connection electrode ANE. Accordingly, the second capacitor C2 may be formed between the first and second source metal layers SDL1 and SDL2.

The low-level voltage line VSL may not be disposed in the display area DA, and the voltage of the first electrode AE of the light-emitting element ED may be stabilized through the second capacitor C2 electrically connected to the driving voltage line VDL. As the display device 10 may include the first capacitor C1 formed between the first and second gate layers GTL1 and GTL2 and the second capacitor C2 formed between the first and second source metal layers SDL1 and SDL2, the area of the pixel circuit can be reduced by reducing the line width and pixel design space, and the voltage drop (IR drop) can be reduced. Accordingly, the display device 10 can be readily employed for a small-sized device with high-resolution.

In FIG. 2, the display panel 100 may include a substrate SUB, a transistor layer TFTL, an emission material layer EDL and an encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide PI. For another example, the substrate SUB may include a glass material or a metal material.

The transistor layer TFTL may include a metal layer BML, a buffer layer BF, an active layer ACTL, a first gate insulator GI1, a first gate layer GTL1, a second gate insulator GI2, a second gate layer GTL2, an interlayer dielectric layer ILD, a first source metal layer SDL1, a first via layer VIA1, a second source metal layer SDL2, and a second via layer VIA2. The first and second gate layers GTL1 and GTL2 may include a first material, and the first and second source metal layers SDL1 and SDL2 may include a second material different from the first material. For example, the line width of the first and second source metal layers SDL1 and SDL2 may be greater than the line width of the first and second gate layers GTL1 and GTL2, and the resistance of the first and second source metal layers SDL1 and SDL2 may be smaller than the resistance of the first and second gate layers GTL1 and GTL2.

The metal layer BML may be disposed on the substrate SUB. The metal layer BML may include first to third metal layers BML1, BML2 and BML3. The first metal layer BML1 may be disposed under or below the first transistor T1 and may overlap the semiconductor region ACT1 of the first transistor T1. The first metal layer BML1 can block light incident from below the first transistor T1.

The second metal layer BML2 may be disposed under or below the second transistor T2 and may overlap the semiconductor region ACT2 of the second transistor T2. The second metal layer BML2 can block light incident from below the second transistor T2.

The third metal layer BML3 may be disposed under or below the third transistor T3 and may overlap the semiconductor region ACT3 of the third transistor T3. The third metal layer BML3 can block light incident from below the third transistor T3.

The buffer layer BF may be disposed on the metal layer BML. For example, the buffer layer BF may include an inorganic film that can prevent the permeation of air or moisture. For example, the buffer layer BF may include a plurality of inorganic films stacked alternately each other.

The active layer ACTL may be disposed on the buffer layer BF. The active layer ACTL may include an oxide-based material. The active layer ACTL may include the semiconductor regions ACT1, ACT2 and ACT3, the drain electrodes DE1, DE2 and DE3, and the source electrodes SE1, SE2 and SE3 of the first to third transistors T1, T2 and T3, respectively.

The first gate insulator GI1 may be disposed on the active layer ACTL. The first gate insulator GI1 may insulate the active layer ACTL from the first gate layer GTL1.

The first gate layer GTL1 may be disposed on the first gate insulator GI1. The first gate layer GTL1 may include the gate electrodes GE1, GE2 and GE3 of the first to third transistors T1, T2 and T3, respectively.

The second gate insulator GI2 may be disposed on the first gate layer GTL1. The second gate insulator GI2 may insulate the first gate layer GTL1 from the second gate layer GTL2.

The second gate layer GTL2 may be disposed on the second gate insulator GI2. The second gate layer GTL2 may include a first scan line GWL, a first portion GCLa of the second scan line GCL, a connection electrode CNE, and a capacitor electrode CPE.

The interlayer dielectric layer ILD may be disposed on the second gate layer GTL2. The second interlayer dielectric layer ILD2 may insulate the second gate layer GTL2 from the first source metal layer SDL1.

The first source metal layer SDL1 may be disposed on the interlayer dielectric layer ILD. The first source metal layer SDL1 may include the data line DL and the first portion VDLa of the driving voltage line VDL.

The first via layer VIA1 may be disposed on the first source metal layer SDL1. The first via layer VIA1 may insulate the first source metal layer SDL1 from the second source metal layer SDL2.

The second source metal layer SDL2 may be disposed on the first via layer VIA1. The second source metal layer SDL2 may include the anode connection electrode ANE.

The second via layer VIA2 may be disposed on the second source metal layer SDL2. The second via layer VIA2 may insulate the second source metal layer SDL2 from the first electrode AE of the light-emitting element ED.

The emission material layer EDL may include a pixel-defining layer PDL and a light-emitting element ED. The light-emitting element ED may include a first electrode AE, an emissive layer EL, and a second electrode CE.

The pixel-defining layer PDL may be disposed on the second via layer VIA2. The pixel-defining layer PDL may define a plurality of emission areas EA. The pixel-defining layer PDL may include an organic insulating material such as polyimide (PI).

The first electrode AE may be disposed on the second via layer VIA2. The first electrode AE may overlap one of the plurality of emission areas EA defined by the pixel-defining layer PDL. The first electrode AE may receive a driving current from the pixel circuit of the pixel SP.

The emissive layer EL may be disposed on the first electrode AE. For example, the emissive layer EL may be, but is not limited to, an organic emissive layer made of an organic material. If the emissive layer EL is an organic light-emitting layer, in case that the pixel circuit of the pixel SP applies a selectable voltage to the first electrode AE and the second electrode CE receives a common voltage or cathode voltage, holes may move to the organic light-emitting layer EL through a hole transporting layer and electrons may move to the organic light-emitting layer EL through a hole transporting layer, and they combine in the organic light-emitting layer EL to emit light.

The second electrode CE may be disposed on the emissive layer EL. For example, the second electrode CE may be implemented in the form of a common electrode extended across all of the pixels SP, instead of being disposed separately in each of the pixels SP. The second electrode CE may be disposed on the emissive layer EL in the emission areas and may be disposed on the pixel-defining layer PDL in the other areas than the emission area.

The encapsulation layer TFEL may be disposed on the second electrode CE to cover the light-emitting elements ED. The encapsulation layer TFEL may include at least one inorganic film to prevent permeation of oxygen or moisture into the light-emitting elements ED. The encapsulation layer TFEL may include at least one organic film to protect the light-emitting elements ED from particles such as dust.

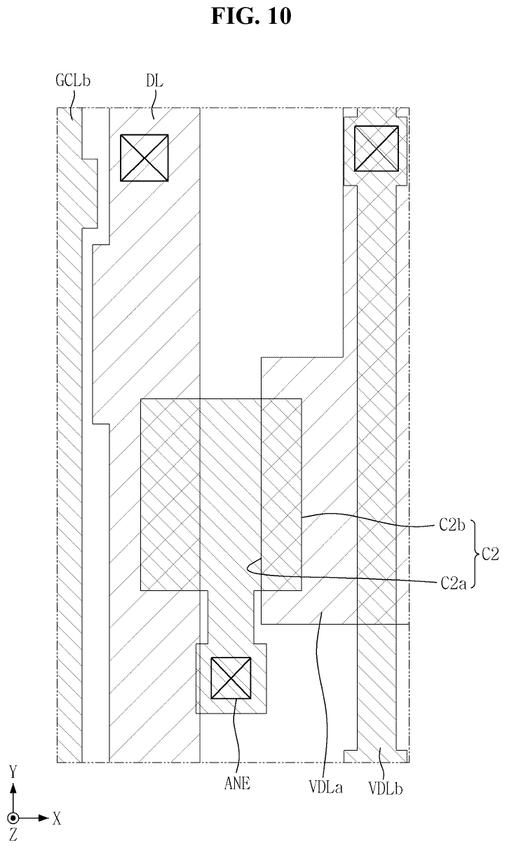

FIG. 10 is a view showing a layout of layers of a pixel in a display device according to an embodiment. The display device of FIG. 10 is substantially identical to the display device of FIG. 6 except for the configuration of first and second source metal layers SDL1 and SDL2; and, therefore, the redundant descriptions will be omitted.

Referring to FIG. 10, the first source metal layer SDL1 may include a data line DL and a first portion VDLa of a driving voltage line VDL. The data line DL may be extended in the y-axis direction and may supply a data voltage to a drain electrode DE2 of a second transistor T2.

The first portion VDLa of the driving voltage line VDL may be extended in the y-axis direction. The first portion VDLa and the second portion VDLb of the driving voltage line VDL may overlap work when viewed from the top and may be connected to each other in the display area DA. The first portion VDLa of the driving voltage line VDL may include a first electrode C2a of a second capacitor C2. The first electrode C2a of the second capacitor C2 may not overlap the second portion VDLb of the driving voltage line VDL.

A second source metal layer SDL2 may include a second portion GCLb of a second scan line GCL, an anode connection electrode ANE, and the second portion VDLb of the driving voltage line VDL. The second portion GCLb of the second scan line GCL may be extended in the y-axis direction, and may be connected to a first portion GCLa of the second scan line GCL of a second gate layer GTL2.

The anode connection electrode ANE may be connected to a capacitor electrode CPE of the second gate layer GTL2 and a first electrode of a light-emitting element ED. The anode connection electrode ANE may include a second electrode C2b of the second capacitor C2.

The second capacitor C2 may include a first electrode C2a and a second electrode C2b. The first and second electrodes C2a and C2b of the second capacitor C2 may overlap each other. The first electrode C2a of the second capacitor C2 may be a part of the first portion VDLa of the driving voltage line VDL, and the second electrode C2b may be a part of the anode connection electrode ANE. Accordingly, the second capacitor C2 may be formed between the first and second source metal layers SDL1 and SDL2.

The low-level voltage line VSL may not be disposed in the display area DA, and the voltage of the first electrode AE of the light-emitting element ED may be stabilized through the second capacitor C2 electrically connected to the driving voltage line VDL. As the display device 10 may include the first capacitor C1 formed between the first and second gate layers GTL1 and GTL2 and the second capacitor C2 formed between the first and second source metal layers SDL1 and SDL2, the area of the pixel circuit can be reduced by reducing the line width and pixel design space, and the voltage drop (IR drop) can be reduced. Accordingly, the display device 10 can be readily employed for a small-sized device with high-resolution.

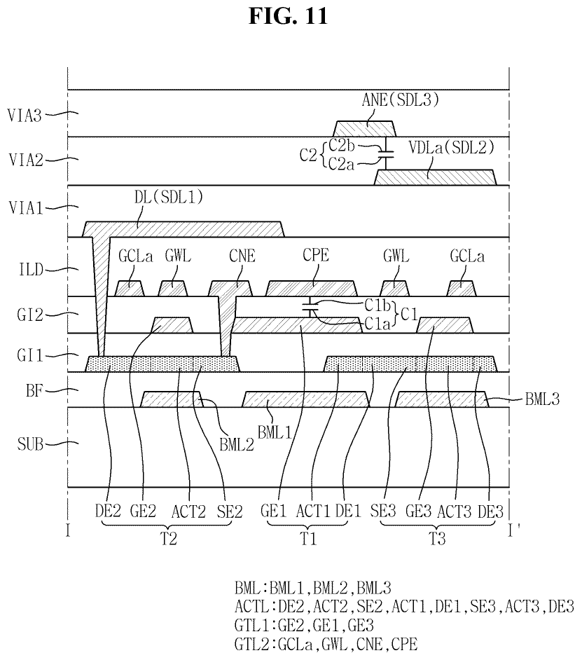

FIG. 11 is a schematic cross-sectional view showing a pixel in a display device according to an embodiment. The display device of FIG. 11 is substantially identical to the display device of FIG. 6 except that the former further may include a third source metal layer SDL3, and that first and second source metal layers SDL1 and SDL2 have a difference configuration; and, therefore, the redundant descriptions will be omitted.

Referring to FIG. 11, a first source metal layer SDL1 may include a data line DL. The data line DL may be extended in the y-axis direction and may supply a data voltage to a drain electrode DE2 of a second transistor T2.

The second source metal layer SDL2 may include a first portion VDLa of a driving voltage line VDL. The first portion VDLa of the driving voltage line VDL may be extended in the y-axis direction. The first portion VDLa of the driving voltage line VDL may include a first electrode C2a of a second capacitor C2.

The third source metal layer SDL3 may be disposed on a second via layer VIA2. A third via layer VIA3 may be disposed on a third source metal layer SDL3 to insulate the third source metal layer SDL3 from a first electrode AE of a light-emitting clement ED. The third source metal layer SDL3 may include an anode connection electrode ANE. The anode connection electrode ANE may be connected to a capacitor electrode CPE of a second gate layer GTL2 and the first electrode AE of the light-emitting element ED. The anode connection electrode ANE may include a second electrode C2b of the second capacitor C2.

The second capacitor C2 may include the first electrode C2a and the second electrode C2b. The first and second electrodes C2a and C2b of the second capacitor C2 may overlap each other. The first electrode C2a of the second capacitor C2 may be a part of the first portion VDLa of the driving voltage line VDL, and the second electrode C2b may be a part of the anode connection electrode ANE. Accordingly, the second capacitor C2 may be formed between the second and third source metal layers SDL2 and SDL3.

The low-level voltage line VSL may not be disposed in the display area DA, and the voltage of the first electrode AE of the light-emitting element ED may be stabilized through the second capacitor C2 electrically connected to the driving voltage line VDL. As the display device 10 may include the first capacitor C1 formed between the first and second gate layers GTL1 and GTL2 and the second capacitor C2 formed between the second and third source metal layers SDL2 and SDL3, the area of the pixel circuit can be reduced by reducing the line width and pixel design space, and the voltage drop (IR drop) can be reduced. Accordingly, the display device 10 can be readily employed for a small-sized device with high-resolution.

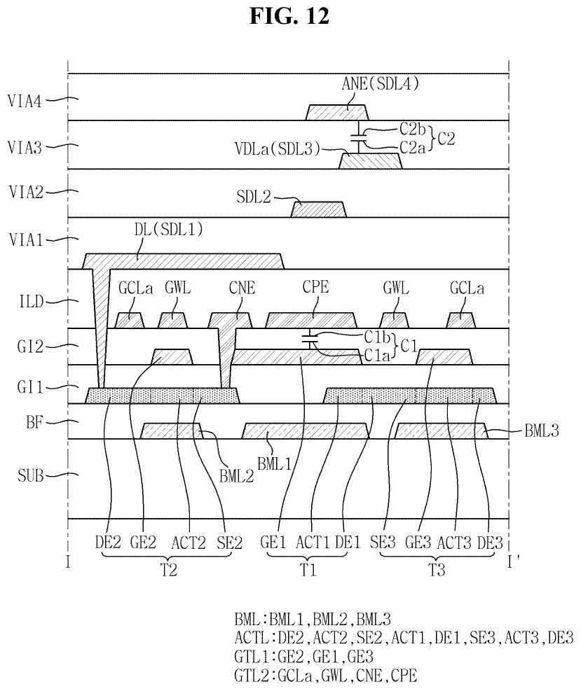

FIG. 12 is a schematic cross-sectional view showing a pixel in a display device according to an embodiment. The display device of FIG. 12 is substantially identical to the display device of FIG. 6 except that the former further may include third and fourth source metal layers SDL3 and SDL4, and that first and second source metal layers SDL1 and SDL2 have a difference configuration; and, therefore, the redundant descriptions will be omitted.

Referring to FIG. 12, a first source metal layer SDL1 may include a data line DL. The data line DL may be extended in the y-axis direction and may supply a data voltage to a drain electrode DE2 of a second transistor T2.

The second source metal layer SDL2 may be disposed on the first source metal layer SDL1. In FIG. 12, the second source metal layer SDL2 may include at least one of a second portion GCLb of a second scan line GCL, and a second portion VDLb of a driving voltage line VDL.

The third source metal layer SDL3 may include a first portion VDLa of the driving voltage line VDL. The first portion VDLa of the driving voltage line VDL may be extended in the y-axis direction. The first portion VDLa of the driving voltage line VDL may include a first electrode C2a of a second capacitor C2.

The fourth source metal layer SDL4 may be disposed on the third via layer VIA3. A fourth via layer VIA4 may be disposed on the fourth source metal layer SDL4 to insulate the fourth source metal layer SDL4 from a first electrode AE of a light-emitting element ED. The fourth source metal layer SDL4 may include an anode connection electrode ANE. The anode connection electrode ANE may be connected to a capacitor electrode CPE of a second gate layer GTL2 and the first electrode AE of the light-emitting element ED. The anode connection electrode ANE may include a second electrode C2b of the second capacitor C2.

The second capacitor C2 may include a first electrode C2a and a second electrode C2b. The first and second electrodes C2a and C2b of the second capacitor C2 may overlap each other. The first electrode C2a of the second capacitor C2 may be a part of the first portion VDLa of the driving voltage line VDL, and the second electrode C2b may be a part of the anode connection electrode ANE. Accordingly, the second capacitor C2 may be formed between the third and fourth source metal layers SDL3 and SDL4.

The low-level voltage line VSL may not be disposed in the display area DA, and the voltage of the first electrode AE of the light-emitting element ED may be stabilized through the second capacitor C2 electrically connected to the driving voltage line VDL. As the display device 10 may include the first capacitor CI formed between the first and second gate layers GTL1 and GTL2 and the second capacitor C2 formed between the third and fourth source metal layers SDL3 and SDL4, the area of the pixel circuit can be reduced by reducing the line width and pixel design space, and the voltage drop (IR drop) can be reduced. Accordingly, the display device 10 can be readily employed for a small-sized device with high-resolution.

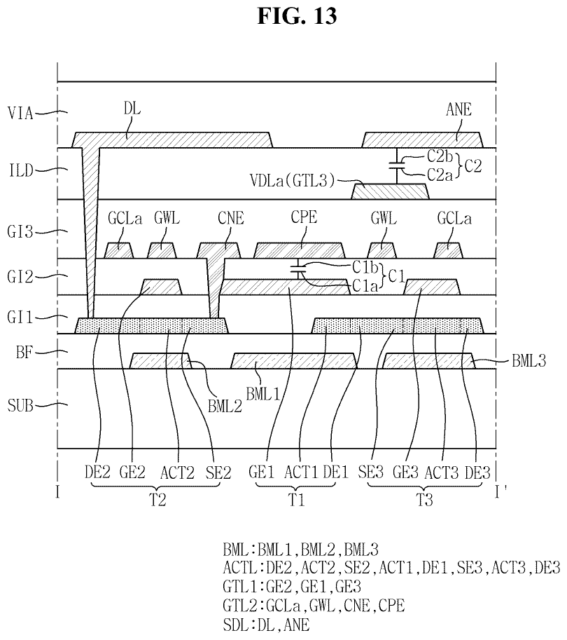

FIG. 13 is a schematic cross-sectional view showing a pixel in a display device according to an embodiment. The display device of FIG. 13 is substantially identical to the display device of FIG. 6 except that the first and second source metal layers SDL1 and SDL2 are eliminated and the former further may include a third gate layer GTL3 and a source metal layer SDL; and, therefore, the redundant descriptions will be omitted.

Referring to FIG. 13, a third gate insulator GI3 may be disposed on a second gate layer GTL2 to insulate the second gate layer GTL2 from the third gate layer GTL3. The third gate layer GTL3 may be disposed on the third gate insulator GI3 and include a first portion VDLa of a driving voltage line VDL. The first portion VDLa of the driving voltage line VDL may include a first electrode C2a of a second capacitor C2. For example, the third gate layer GTL3 may further include a gate electrode of a transistor or a scan line.

The third gate layer GTL3 may include the same first material as the first and second gate layers GTL1 and GTL2, and the source metal layer SDL may include a second material different from the first material. For example, the line width of the source metal layer SDL may be greater than the line width of the first to third gate layers GTL1, GTL2 and GTL3, and the resistance of the source metal layer SDL may be smaller than the resistance of the first to third gate layers GTL1, GTL2 and GTL3.

The source metal layer SDL may include a data line DL and an anode connection electrode ANE. The data line DL may be extended in the y-axis direction and may supply a data voltage to a drain electrode DE2 of a second transistor T2.

The anode connection electrode ANE may be connected to a capacitor electrode CPE of the second gate layer GTL2 and a first electrode of a light-emitting element ED. The anode connection electrode ANE may include a second electrode C2b of the second capacitor C2.

The second capacitor C2 may include a first electrode C2a and a second electrode C2b. The first and second electrodes C2a and C2b of the second capacitor C2 may overlap each other. The first electrode C2a of the second capacitor C2 may be a part of the first portion VDLa of the driving voltage line VDL, and the second electrode C2b may be a part of the anode connection electrode ANE. Accordingly, the second capacitor C2 may be formed between the third gate layer GTL3 and the source metal layer SDL.

The low-level voltage line VSL may not be disposed in the display area DA, and the voltage of the first electrode AE of the light-emitting element ED may be stabilized through the second capacitor C2 electrically connected to the driving voltage line VDL. As the display device 10 may include the first capacitor Cl formed between the first and second gate layers GTL1 and GTL2 and the second capacitor C2 formed between the third gate layer GTL3 and the source metal layer SDL, the area of the pixel circuit can be reduced by reducing the line width and pixel design space, and the voltage drop (IR drop) can be reduced. Accordingly, the display device 10 can be readily employed for a small-sized device with high-resolution.

The display device according to an embodiment of the disclosure can be applied to various electronic devices. The electronic device according to the an embodiment of the disclosure includes the display device described above, and may further include modules or devices having additional functions in addition to the display device.

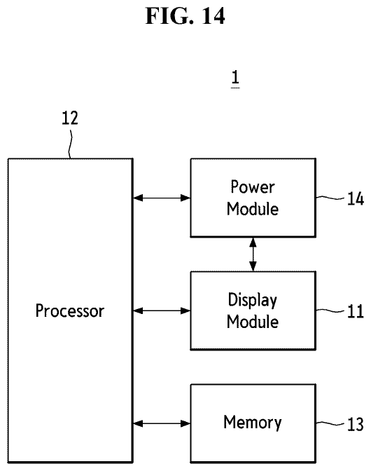

FIG. 14 is a block diagram of an electronic device according to an embodiment of the disclosure.

Referring to FIG. 14, the electronic device 1 according to an embodiment of the disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the an embodiment of the disclosure may be included in the display device 10 according to the embodiments of the disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

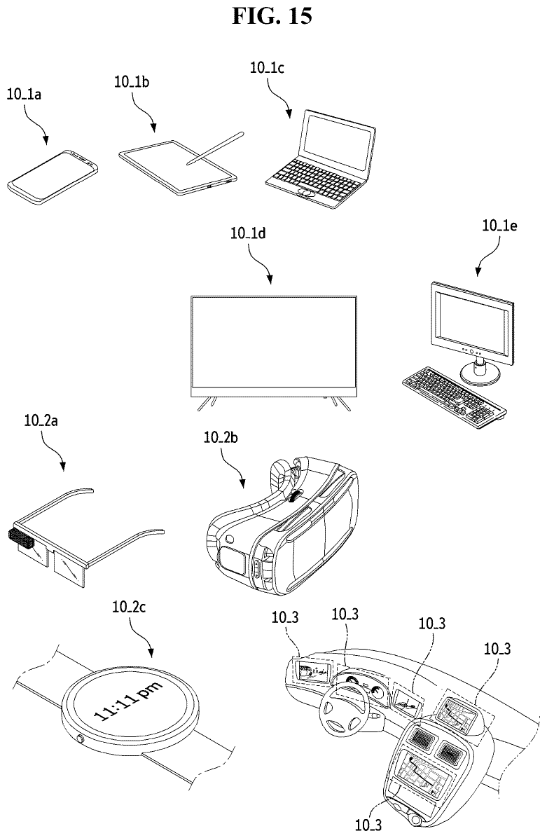

FIG. 15 is a schematic diagram of an electronic device according to various embodiments of the disclosure.

Referring to FIG. 15, various electronic devices to which display devices 10 according to embodiments of the disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

What is claimed is:

1. A display device comprising:
a light-emitting element disposed on a substrate;
a driving voltage line supplying a driving voltage;
a first transistor that controls a driving current supplied to the light-emitting element;
a second transistor that provides a data voltage to a gate electrode of the first transistor;
a third transistor that provides a driving voltage to a drain electrode of the first transistor;
a first capacitor comprising a first electrode electrically connected to the gate electrode of the first transistor and a second electrode electrically connected to a first electrode of the light-emitting element; and
a second capacitor comprising a first electrode electrically connected to the driving voltage line and a second electrode electrically connected to the first electrode of the light-emitting element,
wherein the first electrode and the second electrode of the second capacitor are disposed above the first electrode and the second electrode of the first capacitor.

2. The display device of claim 1, further comprising:
a metal layer disposed on the substrate;
an active layer disposed on the metal layer, the active layer comprising a semiconductor region of each of the first transistor, the second transistor and the third transistor;
a first gate layer disposed on the active layer and comprising a gate electrode of each of the first transistor, the second transistor and the third transistor;
a second gate layer disposed on the first gate layer;
a first source metal layer disposed on the second gate layer; and
a second source metal layer disposed on the first source metal layer, wherein
the first gate layer and the second gate layer include a first material, and
the first source metal layer and the second source metal layer include a second material different from the first material.

3. The display device of claim 2, wherein the active layer includes an oxide-based semiconductor region.

4. The display device of claim 2, wherein
the first electrode of the first capacitor is formed as the first gate layer, and the second electrode of the first capacitor is formed as the second gate layer, and
the first electrode of the second capacitor is formed as the first source metal layer, and the second electrode of the second capacitor is formed as the second source metal layer.

5. The display device of claim 2, wherein the driving voltage line comprises:
a first portion formed as the first source metal layer and extended in a first direction; and
a second portion formed as the second source metal layer and extended in the first direction.

6. The display device of claim 5, wherein the first portion of the driving voltage line comprises the first electrode of the second capacitor, and
the second portion of the driving voltage line supplies the driving voltage to a drain electrode of the third transistor.

7. The display device of claim 6, further comprising:
an anode connection electrode formed as the second source metal layer, comprising the second electrode of the second capacitor, and electrically connecting a source electrode of the first transistor to the first electrode of the light-emitting element.

8. The display device of claim 5, further comprising:
a display area comprising the light-emitting element, the first transistor, the second transistor and the third transistor, and the first capacitor and the second capacitor; and
a non-display area surrounding the display area,
wherein the first portion and the second portion of the driving voltage line are spaced apart from each other in the display area and connected to each other in the non-display area.

9. The display device of claim 5, wherein the first portion and the second portion of the driving voltage line overlap each other and are connected to each other in a display area.

10. The display device of claim 2, further comprising a third source metal layer disposed on the second source metal layer,
wherein the first electrode of the second capacitor is formed as the second source metal layer, and the second electrode of the second capacitor is formed as the third source metal layer.

11. The display device of claim 2, further comprising:
a third source metal layer disposed on the second source metal layer; and
a fourth source metal layer disposed on the third source metal layer,
wherein the first electrode of the second capacitor is formed as the third source metal layer, and the second electrode of the second capacitor is formed as the fourth source metal layer.

12. The display device of claim 1, further comprising:
a metal layer disposed on the substrate;
an active layer disposed on the metal layer, the active layer comprising a semiconductor region of each of the first transistor, the second transistor and the third transistor;
a first gate layer disposed on the active layer and comprising a gate electrode of each of the first transistor, the second transistor and the third transistor;
a second gate layer disposed on the first gate layer;
a third gate layer disposed on the second gate layer; and
a source metal layer disposed on the third gate layer,
wherein the first gate layer, the second gate layer and the third gate layer include a first material, and the source metal layer includes a second material different from the first material.

13. The display device of claim 12, wherein
the first electrode of the first capacitor is formed as the first gate layer, and the second electrode of the first capacitor is formed as the second gate layer, and
the first electrode of the second capacitor is formed as the third gate layer, and the second electrode of the second capacitor is formed as the source metal layer.

14. A display device comprising:
a light-emitting element disposed on a substrate;
a driving voltage line comprising a first portion extended in a first direction and a second portion disposed on the first portion and extended in the first direction;
a first transistor that controls a driving current supplied to the light-emitting element;
a capacitor electrode disposed on a gate electrode of the first transistor and electrically connected to a first electrode of the light-emitting element;
a second transistor that supplies a data voltage to the gate electrode of the first transistor;
a third transistor that receives a driving voltage from the second portion of the driving voltage line to supply the driving voltage to a drain electrode of the first transistor;
an anode connection electrode formed as a same layer as the second portion of the driving voltage line and electrically connecting the first transistor to the light-emitting element;
a first capacitor comprising a first electrode comprising the gate electrode of the first transistor, and a second electrode corresponding to a part of the capacitor electrode; and
a second capacitor comprising a first electrode corresponding to a part of the first portion of the driving voltage line, and a second electrode corresponding to a part of the anode connection electrode.

15. The display device of claim 14, further comprising:
a metal layer disposed on the substrate;
an active layer disposed on the metal layer, the active layer comprising a semiconductor region of each of the first transistor, the second transistor and the third transistor;
a first gate layer disposed on the active layer, the first gate layer comprising a gate electrode of each of the first transistor, the second transistor and the third transistor;
a second gate layer disposed on the first gate layer;
a first source metal layer disposed on the second gate layer; and
a second source metal layer disposed on the first source metal layer,
wherein the first gate layer and the second gate layer include a first material, and the first source metal layer and the second source metal layer include a second material different from the first material.

16. The display device of claim 15, wherein
the gate electrode of the first transistor is formed as the first gate layer, and the capacitor electrode is formed as the second gate layer, and
the first portion of the driving voltage line is formed as the first source metal layer, and the anode connection electrode is formed as the second source metal layer.

17. The display device of claim 15, further comprising:
a third source metal layer disposed on the second source metal layer,
wherein the first portion of the driving voltage line is formed as the second source metal layer, and the anode connection electrode formed as the third source metal layer.

18. The display device of claim 15, further comprising:
a third source metal layer disposed on the second source metal layer; and a fourth source metal layer disposed on the third source metal layer,
wherein the first portion of the driving voltage line is formed as the third source metal layer, and the anode connection electrode is formed as the fourth source metal layer.

19. The display device of claim 14, further comprising:
a display area comprising the light-emitting element, the first transistor, the second transistor and the third transistor, and the first capacitor and the second capacitor; and
a non-display area surrounding the display area,
wherein the first portion and the second portion of the driving voltage line are spaced apart from each other in the display area and connected to each other in the non-display area.

20. The display device of claim 14, wherein the first portion and the second portion of the driving voltage line overlap each other and are connected to each other in a display area.

21. An electronic device, comprising:
a display module configured to provide an image; and
a processor configured to transmit an image data signal to the display module, and
wherein the display module comprises:
a light-emitting element disposed on a substrate;
a driving voltage line supplying a driving voltage;
a first transistor that controls a driving current supplied to the light-emitting element;
a second transistor that provides a data voltage to a gate electrode of the first transistor;
a third transistor that provides a driving voltage to a drain electrode of the first transistor;
a first capacitor comprising a first electrode electrically connected to the gate electrode of the first transistor and a second electrode electrically connected to a first electrode of the light-emitting element; and
a second capacitor comprising a first electrode electrically connected to the driving voltage line and a second electrode electrically connected to the first electrode of the light-emitting element,
wherein the first electrode and the second electrode of the second capacitor are disposed above the first electrode and the second electrode of the first capacitor.
